(19) United States
(12) Patent Application Publication
(10) Pub. No.: US 2006/0138395 A1
(43) Pub. Date: Jun. 29, 2006

(54) Semiconductor photoelectric surface and its manufacturing method, and photodetecting tube using semiconductor photoelectric surface

(76) Inventors: Yasuyuki Kohno, Hamamatsu-shi (JP); Toshimitsu Nagai, Hamamatsu-shi (JP); Yutaka Hasegawa, Hamamatsu-shi (JP)

Correspondence Address: DRINKER BIDDLE & REATH (DC), 1500 K STREET, N.W., SUITE 1100, WASHINGTON, DC, 20005-1209, US

(21) Appl. No.: 10/515,112

(22) PCT Filed: May 21, 2003
(86) PCT No.: PCT/JP03/06361

§ 371 Date: Jan. 26, 2006

(30) Foreign Application Priority Data
May 21, 2002 (JP) 2002-146567

(51) Int. Cl. H01L 29/06

(52) U.S. Cl. 257/10

(57) ABSTRACT

A semiconductor photocathode of the present invention is provided with: a support substrate 10; a photoelectric surface 30 which is formed of a plurality of semiconductor layers layered on this support substrate 10 and which emits photoelectrons from a photoelectron emitting surface 341 in response to the incidence of light to be detected; and a metal electrode 35 which is formed in film form so as to coat at least a portion of support substrate 10 and a portion of photoelectric surface 30 and which makes ohmic contact with the photoelectric surface, wherein metal electrode 30 in film form includes titanium and the electron affinity of photoelectron emitting surface 341, which is an exposed portion of photoelectric surface 30 without being coated with metal electrode 35 in film form, is in a negative condition.

### TECHNICAL FIELD

The present invention relates to a semiconductor photocathode (NEA semiconductor photocathode) where the electron affinity of the photoelectron emitting surface is in a negative condition and to a manufacturing method for the same as well as to a photodetector tube (a photoelectric tube, a photomultiplier tube or the like) using this semiconductor photocathode.

### BACKGROUND ART

Residual gas in the vicinity of a photocathode causes noise (after pulse) at the time of measurement in a photodetector tube such as a photomultiplier tube and, therefore, it is important to remove residual gas in the vicinity of the photocathode. In particular, it is very important in a photomultiplier tube to remove residual gas between the photocathode and the first dynode (secondary photomultiplying part), enhancing the vacuum level within the vacuum tube, in order to reduce the after pulse. A method for sputtering a titanium wire within the vacuum tube so as to getter residual gas in order to enhance the vacuum level within a photomultiplier tube is conventionally known.

In addition, Japanese Published Unexamined Patent Application No. H7-335777 describes a technology where a metal having a gettering effect such as titanium or chromium is placed within a space as a technology used for preventing outgas activity in the space formed of the cap and header of an optical semiconductor device. It is effective to provide a getter, such as titanium or chromium, having a gettering effect in the vicinity of the photocathode in a photomultiplier tube or the like in order to getter residual gas in the vicinity of the photocathode that causes after pulse.

### DISCLOSURE OF THE INVENTION

However, in the case of a compact photomultiplier tube or the like, it is extremely difficult to provide a getter using a conventional titanium wire in the vicinity of the photocathode due to a small inner space. In particular, in the case where a conventional getter is provided between the photocathode and the first dynode in a photomultiplier tube, the distance between the getter and the dynode becomes small and, therefore, the characteristics are negatively effected by heat at the time of getter activation causing a significant reduction in the cathode sensitivity or in the gain.

Therefore, an object of the invention is to achieve miniaturization of a photomultiplier tube or the like by allowing an effective gettering of residual gas in the vicinity of the photocathode in a compact photomultiplier tube or the like having a small inner space.

In order to achieve the above-described object, a semiconductor photocathode of the present invention is provided with: a support substrate; a photoelectric surface which is formed of a plurality of semiconductor layers layered on this support substrate and which emits photoelectrons from a photoelectron emitting surface in response to the incidence of light to be detected; and a metal electrode in film form which is formed in film form so as to coat at least a portion of the support substrate and a portion of the photoelectric surface and which makes ohmic contact with the photoelectric surface, wherein the metal electrode in film form includes titanium and the electron affinity of the photoelectron emitting surface which is an exposed portion of the photoelectric surface without being coated with the metal electrode in film form is in a negative condition.

The metal electrode in film form may be characterized by being made of metal titanium; may be characterized by being a metal electrode in film form having a layered structure of titanium and chromium; or may be characterized by being a mixture of titanium and chromium.

As a result of this, the metal electrode in film form serves as an ohmic electrode for an electrical connection of the photoelectric surface and for the supply of electrons to the photoelectric surface, and in addition, serves as a getter having an effect of gettering a residual gas due to the activation of titanium that is included in the electrode. Furthermore, the electrode in film form that includes titanium is installed in the vicinity of the photoelectric surface and, therefore, residual gas in the vicinity of the photoelectric surface can be effectively gettered. In addition, this electrode is in film form and provides a small bulk, making it possible to be easily installed inside a photomultiplier tube or the like and, therefore, miniaturization of the photomultiplier tube or the like can be achieved.

In addition, a manufacturing method for the above-described semiconductor photocathode is provided with: the first step of forming a photoelectric surface of a plurality of semiconductor layers layered on a support substrate; the second step of forming a metal electrode in film form so as to coat at least a portion of said support substrate and a portion of the photoelectric surface and so as to make ohmic contact with the photoelectric surface; the third step of heating, and thereby heat cleaning, the support substrate, the photoelectric surface and the metal electrode in film form, in a vacuum; and the fourth step of carrying out an activation process on the photoelectron emitting surface, which is an exposed portion of the photoelectric surface without being coated with the metal electrode in film form, so as to convert the electron affinity to a negative condition.

As a result of this, the titanium that is included in the metal electrode in film form, which has been formed in the second step, is activated through heating at the time of the heat cleaning of the third step so as to have a gettering effect. That is to say, the heat cleaning process of the second step also serves as a process for activating titanium, thus, have a gettering effect, thereby making the gettering process which is separately required in the prior art unnecessary.

A photodetector tube using a semiconductor photocathode as described above is provided with: a cathode formed of a semiconductor photocathode as described above; an anode for collecting photoelectrons emitted from the photoelectron emitting surface of the semiconductor photocathode; and a vacuum container for containing the cathode and the anode.

In addition, a photodetector tube using a semiconductor photocathode as described above is provided with: a cathode formed of a semiconductor photocathode as described above; a secondary photomultiplying part for secondarily photomultiplying photoelectrons emitted from the photoelectron emitting surface of the semiconductor photocathode; an anode for collecting secondarily photomultiplied electrons; and a vacuum container for containing the cathode, the secondary photomultiplying part and the anode.

### BRIEF DESCRIPTION OF THE DRAWINGS

FIG. 1A is a plan view showing a photoelectric surface 30 and a plate 10 of a glass surface as viewed from the vacuum side;

FIG. 1B is a cross sectional view along line I-I indicated with arrows of photoelectric surface 30 and plate 10 of a glass surface shown in FIG. 1A;

FIG. 2A is a cross sectional view of an intermediate product during a manufacturing process for a semiconductor photocathode;

FIG. 2B is a cross sectional view of an intermediate product during the manufacturing process for the semiconductor photocathode;

FIG. 2C is a cross sectional view of an intermediate product during the manufacturing process for the semiconductor photocathode;

FIG. 2D is a cross sectional view of an intermediate product during the manufacturing process for the semiconductor photocathode;

FIG. 2E is a cross sectional view of an intermediate product during the manufacturing process for the semiconductor photocathode;

FIG. 2F is a cross sectional view of an intermediate product during the manufacturing process for the semiconductor photocathode; and

FIG. 3 is a cross sectional view of a photodetector tube according to an embodiment.

### BEST MODES FOR CARRYING OUT THE INVENTION

A semiconductor photocathode according to an Embodiment of the present invention is described in reference to the drawings. The same symbols are attached to the same parts so that the same descriptions can be omitted in cases where possible.

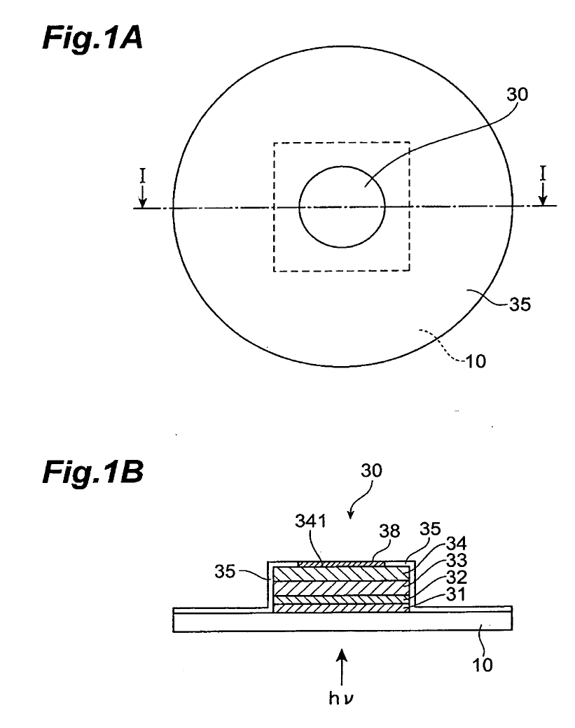

FIG. 1A is a plan view of a photoelectric surface 30 and a plate of a glass surface 10 as viewed from the vacuum side.

FIG. 1B is a cross-sectional view along line I-I indicated by arrows of photoelectric surface 30 and the plate of a glass surface 10 shown in FIG. 1A. Here, for the sake of description, the scale of enlargement in the longitudinal direction is greater than the scale of enlargement in the lateral direction in FIG. 1B.

Light to be detected (hν) enters into photoelectric surface 30 from the lower side of FIG. 1B, wherein the region on the upper side of the photoelectric surface is set to a vacuum condition in FIG. 1B. As shown in FIG. 1B, photoelectric surface 30 is formed by layering a plurality of semiconductor layers 33 and 34 on glass surface 10. A reflection preventing film 32 made of Si₃N₄ is formed on and adheres to the plate of glass surface 10 (support substrate) so as to have a film thickness corresponding to the wavelength of the light to be detected, which is a detection object, by means of an adhesive layer 31 made of SiO₂.

A window layer 33 made of p type AlGaAsP having a thickness of 0.01 μm or greater is formed on reflection preventing film 32 as an epitaxial layer. When light to be detected (hν) enters into the plate of glass surface 10 as shown by the arrow in FIG. 1B, the light transmits through the plate of glass surface 10 and reflection preventing film 32 without being attenuated, and the light having a wavelength shorter than that of the light to be detected from among the light that is transmitted is blocked by window layer 33. Then, a light absorbing layer 34 having a thickness of 0.1 μm to 2 μm and made of p type GaAsP having an energy band gap that is smaller than that of window layer 33 is formed on window layer 33 as an epitaxial layer, and absorbs the light to be detected that has transmitted through window layer 33 so as to emit photoelectrons.

An extremely thin active layer 38 made of Cs₂O is uniformly formed on the center portion of the upper surface of light absorbing layer 34 so as to sufficiently lower the work function of the upper surface of light absorbing layer 34, and therefore, a photoelectron emitting surface 341 of light absorbing layer 34 is in a condition where the electron affinity is negative, that is to say, in a so-called NEA (negative electron affinity) condition. Therefore, when a great amount of photoelectrons generated by the incident light have reached the vicinity of an active layer 38 without being eliminated, they are easily emitted to the outside.

In addition, a titanium electrode 35 in film form (metal electrode in film form) is formed of metal titanium, making ohmic contact with light absorbing layer 34 on the photoelectron emitting surface 341 side. Titanium electrode 35 in film form, having a film thickness of approximately 50 nm, is formed toward the peripheral portion of the plate of glass surface 10 starting from the peripheral portion of the upper surface of light absorbing layer 34 so that light absorbing layer 34 can make an electrical connection.

Titanium electrode 35 in film form is formed so as to coat the peripheral portion of the upper surface of light absorbing layer 34, so as to continue toward the peripheral portion of the plate of glass surface 10, and so as to coat the plate of glass surface 10. The center portion of the upper surface of light absorbing layer 34 is not covered with electrode 35 in film form, and thus photoelectrons generated by the light to be detected that has entered in the direction from the plate of the glass surface are allowed to be transmitted.

The working effects of the above-described semiconductor photocathode are described in the following. Metal titanium is used as the material of electrode 35 in film form that makes ohmic contact with photoelectron emitting surface 341 of the above-described semiconductor photocathode. As a result of this, electrode 35 in film form makes an electrical connection for photoelectric surface 30 so as to work as an ohmic electrode for the application of a voltage to photoelectric surface 30, and also so as to work as a getter having an effect of gettering residual gas due to the activation of titanium.

Electrode 35 in film form made of metal titanium is installed in the vicinity of photoelectric surface 30, and thereby, residual gas in the vicinity of the photoelectric surface can be effectively gettered. In addition, this electrode 35 is in film form having a bulk smaller than that of the conventional getter using a titanium wire. As a result of this, easy installment inside a contact photoelectron multiplier tube or the like becomes possible, and miniaturization of a photoelectron multiplier tube or the like can be achieved by using the semiconductor photocathode of the present embodiment.

In the above-described semiconductor photocathode, active layer 38 is not limited to an oxide of an alkaline metal such as Cs₂O, but rather, may be an alkaline metal or a fluoride thereof. In addition, light absorbing layer 34 is not limited to GaAsP, but rather, may be a material of a III-V group compound such as GaP, GaN or GaAs, or of a IV group such as diamond.

In addition, though an electrode made of metal titanium is used as the metal electrode in film form on the above-described semiconductor photocathode, a chromium film is formed, making ohmic contact with the photoelectron emitting surface of the semiconductor photocathode, and a titanium film is formed so as to be layered on the chromium film on the vacuum side, providing a metal electrode in film form having a two-layered structure of chromium and titanium. Chromium has the property of good adhesiveness, and therefore, adhesion between the semiconductor photocathode and the metal electrode in film form is increased by forming the titanium film via the chromium film.

In addition, titanium that is included in the metal electrode in film form is activated so as to have a gettering effect, and therefore, it is necessary for at least a portion of the titanium film to be exposed on the vacuum side, whereas the metal electrode in film form making ohmic contact with the semiconductor photocathode is not limited to a two-layered structure, but rather, may have a multilayered structure of three or more layers. Furthermore, a mixture of another metal (for example, chromium) and titanium may be used for the metal electrode in film form making ohmic contact with the photoelectron emitting surface, as long as the mixture has a gettering effect due to sublimation of titanium toward the vacuum.

Next, a manufacturing method for the above-described semiconductor photocathode is described.

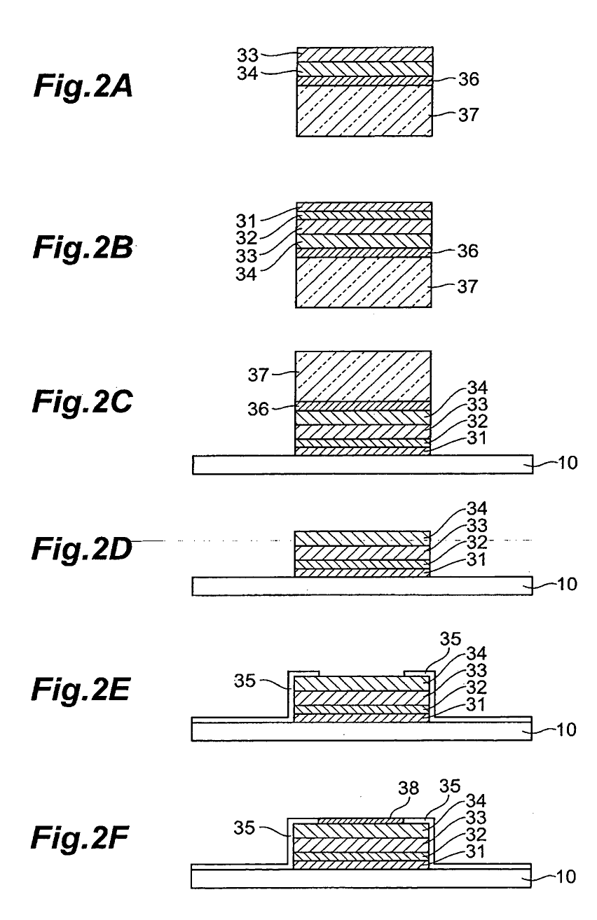

FIG. 2A, FIG. 2E, FIG. 2C, FIG. 2D, FIG. 2E and FIG. 2F are cross-sectional views of intermediate products during the manufacturing process for the semiconductor photocathode.

First, in the first step, an etching stop layer 36, a light absorbing layer 34 and a window layer 33 are epitaxially grown in sequence on a semiconductor substrate 37 made of GaAs so that a semiconductor multilayered film is produced (see FIG. 2A). After that, a reflection preventing film 32 is formed on window layer 33 by using a CVD method., and furthermore, an adhesive layer 31 made of SiO₂ is deposited on reflection preventing film 32 (see FIG. 2B).

Then, a plate of a glass surface 10 in disc form is heated to approximately 550° C. in a vacuum or in an inert gas so as to be thermally fused with adhesive layer 31 (see FIG. 2C). After this has been cooled down to room temperature, semiconductor substrate 37 and etching stop layer 36 are removed by means of wet etching so that light absorbing layer 34 is exposed (see FIG. 2D). Next, in the second step, a titanium film is deposited from vapor form on a portion of light absorbing layer 34 other than photoelectric surface 30 so as to form a titanium electrode 35 in film form which makes contact with light absorbing layer 34 on the photoelectron emitting surface side (see FIG. 2E).

Next, in the third step, the gained photoelectric surface 30, along with the plate of glass surface 10, is heated to approximately 700° C. in a vacuum so as to be heat cleaned. Finally, in the fourth step, an active layer 38 is formed in a vacuum in order to convert the electron affinity to a negative condition by carrying out an activation process on the photoelectron emitting surface (see FIG. 2F).

Working effects of the above-described manufacturing method are described in the following. The formation (second step) of titanium electrode 35 in film form is carried out before the heat cleaning process (third step), and therefore, titanium, which is the material of electrode 35 in film form that has already been formed, is activated through heating in the heat cleaning process, and thus, the activated titanium has a gettering effect. That is to say, the heat cleaning process is carried out at the same time as the process for activating titanium, making the gettering process which is separately required in the prior art unnecessary.

The manufacturing method for a semiconductor photocathode of the present invention is not limited to the above-described embodiment. Though in the second step of the above-described manufacturing method a metal electrode is formed in a manner where a titanium film makes direct contact with the photoelectric surface, according to the present invention, another metal (for example, chromium) is made to contact with the photoelectric surface so as to form a metal film, and after that, a titanium film is overlapped on the vacuum tube side thereof, and thereby, a metal electrode in film form having a layered structure of titanium and another metal may be formed. In addition, the metal electrode in film form is not limited to a titanium film, but rather, an electrode in film form of a mixture of titanium and chromium may be formed.

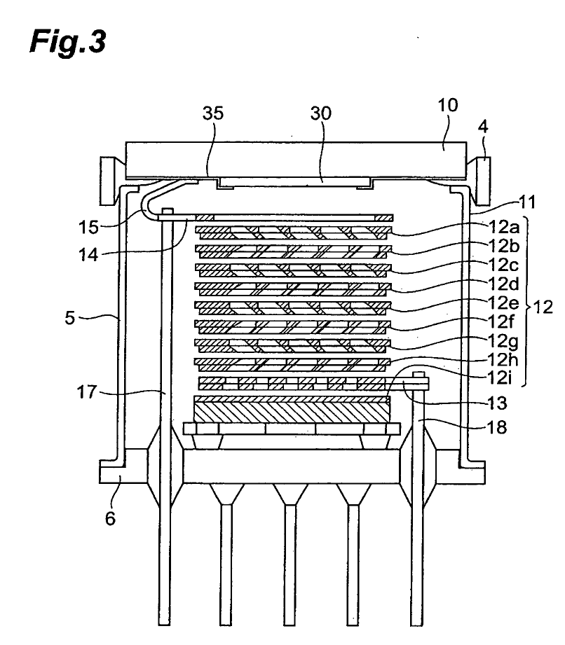

Next, an embodiment of a photodetector tube using the above-described semiconductor photocathode is described. FIG. 3 is a cross-sectional view of a photodetector tube using the above-described semiconductor photocathode. This photodetector tube is a photomultiplier tube having a metal channel type dynode (secondary photomultiplying part), and has a so-called transmission type photoelectric surface 30 wherein a photoelectric surface is provided on and makes contact with the plate of a glass surface on the inner side of a vacuum tube.

In addition, semiconductor photocathode 30 of this photomultiplier tube forms a cathode, and this photomultiplier tube has a dynode 12 for secondarily photomultiplying photoelectrons that have been emitted from the semiconductor photocathode, an anode 13 for collecting electrons, and a vacuum tube 11 (vacuum container) for containing the cathode and the anode. Photoelectric surface 30 is provided so as to make contact with the plate of glass surface 10 on the inner side of the vacuum tube, whereas titanium electrode 35 in film form makes ohmic contact with the photoelectron emitting surface of photoelectric surface 30. The plate of glass surface 10 is secured to one end of a cylinder that forms the main body of vacuum tube 11, and the other end of the cylinder that forms vacuum tube 11 is also sealed airtight using glass, so that the inside of vacuum tube 11 can be maintained in a vacuum condition.

Photoelectric surface 30 is connected to the outside via titanium electrode 35 in film form, a cathode contact 15, a focusing electrode 14 and a cathode electric lead 17. Photoelectric surface 30 and titanium electrode 35 in film form make ohmic contact, and therefore, photoelectric surface 30 is supplied with electrons from the outside. Anode 13 is installed at the other end within vacuum tube 11, and the potential of anode 13 is set to a predetermined potential via an anode electric lead 18.

A dynode part 12 is installed between photoelectric surface 30 and the anode, and is formed of metal channel dynodes 12a, 12b, 12c, 12d, 12e, 12f, 12g and 12h, which sequentially multiply photoelectrons that have been emitted from photoelectric surface 30, and a reflective type final stage dynode 12i for reflecting (multiplying) electrons that have transmitted through the opening provided in anode 13 after being multiplied by dynode 12h, and for allowing the electrons to reenter into anode 13. Metal channel dynodes 12a to 12h are in a form where the same dynodes are installed in repeated and multiple forms. Photoelectric surface 30 is maintained at a potential lower than that of anode 13 via titanium electrode 35 in film form, cathode contact 15, focusing electrode 14 and cathode electric lead 17. A breeder voltage which is positive relative to photoelectric surface 30 is applied to each metal channel dynode 12, and is distributed in a manner where, the closer to anode 13 the dynode is, the higher the voltage applied to the dynode is. Thus, a voltage which is positive relative to dynode 12h is applied to anode 13.

When light to be detected enters into photoelectric surface 30 of the photomultiplier tube, photoelectrons are emitted from photoelectric surface 30, and the emitted photoelectrons enter into first dynode 12a. First dynode 12a emits secondary electrons of which the number is several times greater than the number of photoelectrons that have entered, and the secondary electrodes are accelerated and continuously enter into second dynode 12b. Second dynode 12b also emits secondary electrons of which the number is several times greater than that of electrons that have entered, in the same manner as first dynode 12a. This is repeated nine times, and thereby, the photoelectrons that have been emitted from photoelectric surface 30 are finally multiplied to approximately one million times, and the secondary electrons are corrected by anode 13 so as to exit as an output signal current.

An assembly process of the above-described photomultiplier tube is described in the following. First, a plate of glass surface 10 (a photoelectric surface 30, which has not yet been activated by alkaline, and titanium electrode 35 in film form are already formed), an In ring 4, a side tube 5 and a base 6 are respectively introduced in a transfer unit. At this time, side tube 5 and base 6 are introduced in the condition where resistance welding has already been carried out on side tube 5 and base 6 within another unit. Next, photoelectric surface 30 which is not yet activated by alkaline is heat cleaned, and in addition, is activated by means of alkaline. Dynode part 12 is heated by a heater so as to be outgassed for each chamber, and after that, is activated by means of alkaline. Finally, In ring 4 and the plate of glass surface 10 are pressed against side tube 5 for sealing.

Next, working effects of the above-described photomultiplier tube are described. This photomultiplier tube utilizes the above-described semiconductor photocathode, which works as a getter having the effect of gettering residual gas due to the activation of titanium of titanium electrode 35 in film form. Electrode 35 in film form made of metal titanium is installed in the vicinity of photoelectric surface 30, and therefore, residual gas in the vicinity of the photoelectric surface can be effectively gettered.

In addition, this electrode 35 is in film form having a bulk smaller than that of the getter using a titanium wire according to the prior art. As a result of this, easy installment on the inside of a compact photoelectric multiplier tube or the like such as that in the present embodiment becomes possible so that miniaturization of a photomultiplier tube or the like can be achieved. In addition, heat emission is also not necessary in a position close to another part, such as a dynode, unlike the photomultiplier tube using a getter according to the prior art, and therefore, the properties of the dynode or the like are not negatively affected.

In addition, it is necessary to run a lead line for supplying power to a titanium wire from the outside of the vacuum tube to the inside of the vacuum tube according to the conventional method. On the other hand, in the present embodiment, such a lead line is unnecessary, enhancing the air-tightness of the vacuum tube, and therefore, the invention is effective from the point of view of an increase in the level of vacuum within the vacuum tube.

A photodetector tube of the present invention is not limited to the above-described embodiment. The above-described photodetector tube is a photomultiplier tube having a metal channel type dynode, and is appropriate, in particular, for a photodetector tube to which the present invention is applied, from the point of view of demand in the reduction of after pulse, and from the point of view of overcoming the difficulty in installment of a compact titanium getter. However, it is possible to apply the present invention to a photomultiplier tube having another type of dynode, such as a circular cage type dynode, a box and grid type dynode, a line focus type dynode, a Venetian blind type dynode, a mesh type dynode or a micro-channel plate type dynode.

In addition, it is also possible to apply the present invention to a photomultiplier tube having a multi-channel plate. In addition, it is also possible to apply the present invention to a two-dimensional highly sensitive detector such as an image intensifier tube, a multi-anode photomultiplier tube, an ultrahigh-speed light measuring streak tube or a photo-counting image tube for measuring two-dimensional faint light. Furthermore, it is possible to apply the present invention to a photoelectric tube having no dynode part, or a streak tube.

The semiconductor photocathode of the present invention allows effective gettering of residual gas in the vicinity of the photoelectric surface that causes after pulse even when being used for a compact photomultiplier tube or the like having a small inner space, and can achieve miniaturization of a photomultiplier tube or the like. Furthermore, reduction in the number of parts and shortening of the assembly process can be achieved.

### INDUSTRIAL APPLICABILITY

The present invention can be applied to a semiconductor photocathode (NEA semiconductor photocathode) where the electron affinity of the photoelectron emitting surface is in a negative condition, and to a manufacturing method for the same, as well as to a photodetector tube (a photoelectric tube, a photomultiplier tube or the like) using this semiconductor photocathode.

1. A semiconductor photocathode, comprising:
a support substrate;
a photoelectric surface which is formed of a plurality of semiconductor layers, including a light absorption layer, layered on this support substrate, and which emits photoelectrons from a photoelectron emitting surface in response to an incidence of light to be detected; and
a metal electrode in film form which is formed in film form so as to coat at least a portion of the support substrate and a portion of the light absorption layer of the photoelectric surface and which makes ohmic contact with the light absorption layer of the photoelectric surface, wherein
the metal electrode in film form includes titanium and an electron affinity of the photoelectron emitting surfaces which is an exposed portion of the photoelectric surface without being coated with the metal electrode in film form, is in a negative condition.

2. The semiconductor photocathode according to claim 1,
wherein the metal electrode in film form is made of metal titanium.

3. The semiconductor photocathode according to claim 1,
wherein the metal electrode in film form is a metal electrode in film form having a layered structure of titanium and chromium.

4. The semiconductor photocathode according to claim 1,
wherein the metal electrode in film form is a mixture of titanium and chromium.

5. A photodetector tube, comprising:
a cathode formed of the semiconductor photocathode according to claim 1;
an anode for collecting photoelectrons emitted from the photoelectron emitting surface of the semiconductor photocathode; and
a vacuum container for containing the cathode and the anode.

6. A photodetector tube, comprising:
a cathode formed of the semiconductor photocathode according to claim 1;
a secondary photomultiplying part for secondarily photomultiplying photoelectrons emitted from the photoelectron emitting surface of the semiconductor photocathode;
an anode for collecting secondarily photomultiplied electrons; and
a vacuum container for containing the cathode, the secondary photomultiplying part and the anode.

7. A manufacturing method for a semiconductor photocathode, comprising:
the first step of forming a photoelectric surface of a plurality of semiconductor layers, including a light absorption layer, layered on a support substrate;
the second step of forming a metal electrode in film form that includes titanium so as to coat at least a portion of the support substrate and a portion of the light absorption layer of the photoelectric surface and so as to make ohmic contact with the light absorption layer of the photoelectric surface;
the third step of heating, and thereby heat cleaning, the support substrate, the photoelectric surface and the metal electrode in film form, in a vacuum; and
the fourth step of carrying out an activation process on the photoelectron emitting surface, which is an exposed portion of the photoelectric surface without being coated with the metal electrode in film form, so as to convert an electron affinity to a negative condition.

8. The manufacturing method for a semiconductor photocathode according to claim 7,
wherein the metal electrode in film form is made of metal titanium.

9. The manufacturing method for a semiconductor photocathode according to claim 7,
wherein the metal electrode in film form is a metal electrode in film form having a layered structure of titanium and chromium.

10. The manufacturing method for a semiconductor photocathode according to claim 7,
wherein the metal electrode in film form is a mixture of titanium and chromium.

11. A semiconductor photocathode, comprising a metal electrode in film form made of titanium which is formed in film form so as to coat a portion of a light absorption layer of a photoelectric surface formed on a support substrate, making ohmic contact with the light absorption layer.

12. The semiconductor photocathode according to claim 1,
wherein the metal electrode in film form coats a peripheral portion of the upper surface of the light absorption layer, is continuously spread toward a peripheral portion of the support substrate and coats a plate of a glass surface.

13. The manufacturing method for a semiconductor photocathode according to claim 7,
wherein the metal electrode in film form coats a peripheral portion of the upper surface of the light absorption layer, is continuously spread toward a peripheral portion of the support substrate and coats a plate of a glass surface.
